(19) United States
(12) Patent Application Publication
(10) Pub. No.: US 2004/0146806 A1
(43) Pub. Date: Jul. 29, 2004

(54) Photo-imageable nanocomposites

(76) Inventors: David H. Roberts, Carlsbad, CA (US); Geoffrey Yuxin Hu, San Diego, CA (US); Maria Teresa A. Castillo, Spring Valley, CA (US)

Correspondence Address: John L. Cordani, Carmody & Torrance LLP, 50 Leavenworth Street, P.O. Box 1110, Waterbury, CT, 06721-1110, US

(21) Appl. No.: 10/353,446

(22) Filed: Jan. 29, 2003

(51) Int. Cl. G03F 7/028

(52) U.S. Cl. 430/287.1; 430/286.1; 430/285.1; 430/284.1; 430/306

(57) ABSTRACT

An improved photopolymerizable resin composition for use in making flexographic printing plates, wherein the resin composition comprises a base polymer, a reactive crosslinking agent, a photoinitiator, and a nanoparticle-sized filler. Printing plates produced using the improved compositions of the invention have increased toughness, less tack, reduced cold flow, and higher hardness as compared to prior art compositions that do not contain nanoparticle fillers.

### FIELD OF THE INVENTION

This invention relates to photopolymerizable resin compositions that contain nanoparticle fillers to produce flexographic printing plates with enhanced performance, including increased toughness, reduced tack, reduced cold flow, and higher hardness.

### BACKGROUND OF THE INVENTION

Photocurable polymers and compositions are well known in the art for forming printing plates and other photosensitive or radiation sensitive articles. In the field of radiation sensitive flexographic printing plates, the plates typically comprise a support and a photosensitive surface or layer from a photocurable composition. Additional layers or surfaces on the plate include slip and release films to protect the photosensitive surface. Prior to processing the plate, the additional layers are removed, and the photosensitive surface is exposed to radiation in an imagewise fashion. The unexposed areas of the surface are then removed in developer baths or by thermal blotting. Typical water-developable photosensitive resin composition are disclosed by U.S. Pat. No. 5, 976,763 to Roberts et al., and U.S. Pat. No. 5,698,371 to Mirle et al, the subject matter of which is herein incorporated by reference in its entirety.

Conventional fillers have been used in rubber formulations for decades to improve the physical properties of the rubber, and to increase the tensile strength and toughness of the final cured elastomer. Illustrative of the many fillers which can be employed are titanium dioxide, lithopone, zinc oxides, calcium silicate, silica aerogel, barium oxide, diatomaceous earth, calcium carbonate, fumed silica, silazane, treated silica, precipitated silica, glass fibers, magnesium oxide, chromic oxides, zirconium oxides, aluminum oxide, alpha quartz, calcined clay, asbestos, carbon, graphite, cork, cotton, synthetic fibers, etc.

Fillers have also been used in photopolymerizable resin compositions. One such process is described in U.S. Pat. No. 3,060,023 to Burg et al., the subject matter of which is herein incorporated by reference in its entirety. Burg et al. disclose that if desired, the photopolymerizable layers can also contain immiscible polymeric or non-polymeric organic or inorganic fillers or reinforcing agents, which are essentially transparent at the wave-lengths used for the exposure of the polymeric material. For example, organophilic silicas, bentonites, silica, powdered glass, colloidal carbon, as well as various types of dyes and pigments in amounts varying with the desired properties of the photopolymerizable layer may be used. The fillers are described as being useful in improving the strength of the composition, reducing tack, and as coloring agents.

However, these filler materials are generally micron-sized particles (I micron) or larger, and can cause significant cloudiness in the resin composition, causing light scattering and loss of imaging resolution due to the interaction of the particles with the imaging radiation. Therefore, toughness and tensile strength in flexo resin systems is generally obtained by adding additional crosslinking monomer to the resin composition, which usually leads to an increase in durometer and brittleness, resulting in less elongation.

Tack-reduction in flexographic resin compositions is most often obtained by post-imaging exposure of the resin composition to short wavelength (“germicidal”) lamps. However, this approach only detacks the surface of the plate, not the interior of the plate. After many printing impressions on a press, the top layer of the plate can thus wear away and reveal the tacky underlayer.

Cold flow is usually addressed in either one of two ways. First, one can reduce the liquid to solid ratio in the resin. However, this limits the formulation latitude. In the alternative, one can edge cure the plate at the factory to seal the edge of the resin. However, this approach requires an additional manufacturing step and also spoils the edge of the resin.

Hardness can be easily obtained by increasing the amount of reactive monomer and/or using more monomer with a higher level of functionality. This usually has the effect of reducing elongation and flexibility of the resin.

Therefore, there is a need in the art to improve the properties of photopolymerizable resin compositions, and in particular, flexographic photopolymerizable resins in a more efficient manner than has been used previously in the prior art. While the use of particulates has been tried in the prior art, there is no teaching or suggestion that smaller particles, such as nanoparticles, can be used to improve the performance characteristics of photopolymerizable resin systems.

Nanoparticle-sized fillers have been used to increase the microbend strength of optical fiber coatings and cables without reducing the fiber test strength and without impairment of the UV curing process due to the opacity of the particulate fillers. U.S. Pat. No. 6,415,090 to Taylor et al., the subject matter of which is herein incorporated by reference in its entirety, describes the use of nanoclay particulates in increasing the microbend strength of optical fiber coatings. Nanoparticle-size fillers have also been contemplated for use in increasing resistance to compressive deformation and crushing in loose-tube, central-core, and tube-in-tube fiber optic cables, such as in U.S. Pat. No. 6,430,344, to Dixon et al., the subject matter of which is herein incorporated by reference in its entirety.

The purpose of the instant invention is to provide enhanced flexographic plate performance. To that end, the inventors have found that the addition of modest amounts of nanoparticles to photosensitive resin compositions improves the physical properties of the resin. “Nanoparticles” refer to materials that are sized in the nanometer range and may include, for example, spheres and platelets. Other types of particles are also known from the prior art and would be apparent to one of ordinary skill in the art. Nanoparticles for use in the instant invention include particles having an average diameter of less than 1,000 nanometers, preferably less than 100 nanometers, and most preferably less than 10 nanometers.

More specifically, the improved resin composition of the instant invention provides advantages including better toughness for longer on-press runs, less tack for ink and paper fiber accumulation during the run, less tack for more robust plate handling for the plate maker, use as a substitute for high Tg polymers, such as Blendex copolymers, in capping layers, reduced cold flow, and higher hardness for less dot gain in capping layers.

Other potential advantages include provisions of a barrier to oxygen, increased ozone resistance, better ink transfer, and improved substrate adhesion.

### SUMMARY OF THE INVENTION

In accordance with the present invention, the inventors have developed an improved photosensitive resin composition for use in making a flexographic printing plate, wherein the resin composition comprises:

a) a base polymer;

b) a reactive crosslinking agent;

c) a photoinitiator; and

d) a filler, wherein said filler comprises nanoparticles.

In a further embodiment of the invention, the nanoparticles comprise nanoclay particles.

In accordance with the present invention, the improved photosensitive resin composition may be formulated into flexographic plates.

### DETAILED DESCRIPTION OF THE PREFERRED EMBODIMENTS OF THE INVENTION

The inventors have found that the addition of modest amounts of nanoparticles to photosensitive resin compositions improves their physical properties in a variety of ways, including increasing toughness, reducing tack, reduced cold flow, and providing higher hardness.

Generally the addition of nanoparticles in an amount less than 25 percent by weight provides enhanced physical properties to the resin. More preferably, to reduce resin haziness, less than 15 percent by weight of the nanoparticles in the resin composition are used. Most preferably, less than 10 percent by weight of the nanoparticles in the resin composition are used. However, in order to obtain a noticeable effect, at least 0.5 percent by weight of the nanoparticles are required in the resin composition.

To avoid haziness in the resin composition, the particles need to be in the nanometer size regime, otherwise the particles interact with the imaging radiation (ultraviolet or visible light) causing light scatter and loss of imaging resolution. Particles sizes of less than 1,000 nm, preferably less than 100 nm, and most preferably less than 10 nm, are contemplated for use in the instant invention.

Nanoparticles of almost any chemical composition can be used in resin compositions of the instant invention so long as they do not cause shelf life or clarity problems in the resin system. Non-limiting examples of suitable nanoparticles for use in the resin compositions of the instant invention include zinc oxide, titanium oxide, clay, and silicon dioxide nanoparticles, although other suitable nanoparticles would also be known to those skilled in the art.

Preferably, the nanoparticles used in the instant invention comprise clay particles, including, for example, montmorillonite, hectorite, bentonite, kaolinite, attapulgite, and vermiculite, synthetic smectite clays, and other smectite clays. As the most abundant of the smectite clays, montmorillonite is preferably used. The nanoparticles used in the instant invention are generally purified and then treated, or modified, in order to make the polar clay surface less polar. Functional amines may be used to treat the surface of the clay particles. Suitable sources of the montmorillonite clay particles include Nanomer® I.34 TCN, a surface-modified montmorillonite mineral, manufactured by Nanocor Corp., and Cloisite® 10A, a natural montmorillonite modified with a quaternary ammonium salt, manufactured by Southern Clay Products, Inc. Nanomer® I.34 TCN generally has a mean dry particle size of 16-22 microns, while Cloisite® 10A generally has a mean dry particle size of 2-13 microns.

Photosensitive resin systems contemplated for use in the instant invention can be formulated around a wide range of different base polymers. Non-limiting examples of base polymers usable in the instant invention include styrene-isoprene and styrene-isoprene-styrene containing block copolymers, styrene-butadiene and styrene-butadiene-styrene block copolymers, urethane-based systems, polyvinyl alcohol-based systems, cross-linked latex particle-based systems, and blends of the foregoing. Other base polymers are also known to those skilled in the art. U.S. Pat. No. 5,073,477 to Kusuda et al., U.S. Pat. No. 5,731,129 to Koshimura et al., and U.S. Pat. No. 5,698,371 to Mirle et al., the subject matter of which are herein incorporated by reference in their entirety demonstrate suitable examples of base polymers that are usable in the instant invention.

All conventional chemicals typically found formulated in photosensitive resin compositions can be used in compositions of the instant invention, including reactive monomers, oligomers, photoinitiators, inhibitors, dyes, plasticizers, antiozonants, and other additives.

Suitable reactive crosslinking agents include reactive monomers, as well as vinyl ethers, allyl ethers, maleate esters, and fumurate esters. Suitable non-limiting examples of reactive monomers contemplated for use in the instant invention include, but are not limited to, trimethylolpropane triacrylate, hexanediol diacrylate, 1,3-butylene glycol diacrylate, diethylene glycol diacrylate, 1,6-hexanediol diacrylate, neopentyl glycol diacrylate, polyethylene glycol 200 diacrylate, tetraethylene glycol diacrylate, triethylene glycol diacrylate, pentaerythritol tetraacrylate, tripropylene glycol diacrylate, ethoxylated bisphenol-A diacrylate, propylene glycol mono/dimethacrylate, trimethylolpropane diacrylate, di-trimethylolpropane tetraacrylate, triacrylate of tris(hydroxyethyl) isocyanurate, dipentaerythritol hydroxypentaacrylate, pentaerythritol triacrylate, ethoxylated trimethylolpropane triacrylate, triethylene glycol dimethacrylate, ethylene glycol dimethacrylate, tetraethylene glycol dimethacrylate, polyethylene glycol-200 dimethacrylate, 1,6-hexanediol dimethacrylate, neopentyl glycol dimethacrylate, polyethylene glycol-600 dimethacrylate, 1,3-butylene glycol dimethacrylate, ethoxylated bisphenol-A dimethacrylate, trimethylolpropane trimethacrylate, diethylene glycol dimethacrylate, 1,4-butanediol diacrylate, diethylene glycol dimethacrylate, pentaerythritol tetramethacrylate, glycerin dimethacrylate, trimethylolpropane dimethacrylate, pentaerythritol trimethacrylate, pentaerythritol dimethacrylate, pentaerythritol diacrylate, urethane-methacrylate or acrylate oligomers and the like.

Suitable non-limiting examples of oligomers usable in the instant invention include (meth)acrylate terminated urethane oligomers, polybutadiene, liquid isoprene rubber, (meth)acrylated polybutadiene, and polytetrahyrofuran.

Photoinitiators for the photopolymerizable composition include the benzoin alkyl ethers, such as benzoin methyl ether, benzoin ethyl ether, benzoin isopropyl ether and benzoin isobutyl ether. Another class of photoinitiators are the dialkoxyacetophenones exemplified by 2,2-dimethoxy-2-phenylacetophenone, i.e., Irgacure® 65 1 (Ciba-Geigy) and 2,2-diethoxy-2-phenylacetophenone. Still another class of photoinitiators are the aldehyde and ketone carbonyl compounds having at least one aromatic nucleus attached directly to the carboxyl group. These photoinitiators include, but are not limited to benzophenone, acetophenone, o-methoxybenzophenone, acetonaphthalenequinone, methyl ethyl ketone, valerophenone, hexanophenone, alpha-phenyl-butyrophenone, p-morpholinopropiophenone, dibenzosuberone, 4-morpholinobenzophenone, 4′-morpholinodeoxybenzoin, p-diacetylbenzene, 4-aminobenzophenone, 4′-methoxyacetophenone, benzaldehyde, alpha-tetralone, 9-acetylphenanthrene, 2-acetylphenanthrene, 10-thioxanthenone, 3-acetylphenanthrene, 3-acetylindone, 9-fluorenone, 1-indanone, 1,3,5-triacetylbenzene, thioxanthen-9-one, xanthene-9-one, 7-H-benz[de]-anthracen-7-one, 1-naphthaldehyde, 4,4′-bis(dimethylamino)-benzophenone, fluorene-9-one, 1′-acetonaphthone, 2′-acetonaphthone, 2,3-butedione, acetonaphthene, benz[a]anthracene 7.12 diene, etc.

The compositions may also contain other additives, which are known in the art for use in photocurable compositions, e.g., antioxidants, antiozonants, plasticizers, and UV absorbers. To inhibit premature crosslinking during storage of the prepolymer containing compositions of this invention, thermal polymerization inhibitors and stabilizers are added. Such stabilizers are well known in the art, and include, but are not limited to, hydroquinone monobenzyl ether, methyl hydroquinone, amyl quinone, amyloxyhydroquinone, n-butylphenol, phenol, hydroquinone monopropyl ether, phenothiazine, phosphites, nitrobenzene and phenolic-thio compounds, and mixtures thereof. These stabilizers are effective in preventing crosslinking of the prepolymer composition during preparation, processing and storage. Such additives are used in an amount within the range of from about 0.01 to about 4% by weight of the prepolymer.

Compositions of the invention may also optionally contain a plasticizer, which acts to reduce the glass transition temperature of the polymer, thereby easing processibility of the composition. Examples of plasticizers useful in the practice of the present invention include carboxyl, sulfonyl, phosphonyl, ammonium, or amine surfactants, or alkoxylated derivatives thereof, or a mixture of any two or more thereof.

Presently preferred plasticizers contemplated for optional use in the practice of the present invention, include, for example, N,N-bis-hydroxyethyl-9,12-octadecadienamide (Scher Chem. Schercomid SLF), N-(2-hydroxypropyl)-9-octadecenamide (Scher Chem. Schercomid OMI), N,N-bis(2-hydroxyethyl)-dodecanamide (Scher Chem. Schercomid SL), ethoxylated or propoxylated phenols, ethoxylated or propoxylated nonylphenols, Shellflex® 371, glycerin, ethoxylated glycerin, octylphenoxypoly-ethoxyethanol (Union carbide, Triton X-series), C₆-C₁₈ tert-alkyl ethoxylated amine (Union carbide, Triton RW-series), and the like.

UV light absorbers, or UV light stabilizers, can be used to adjust the photospeed and, therefore, exposure latitude of the polymer material. Numerous materials will be apparent to those skilled in the art.

The most important light stabilizer classes are: 2-hydroxy-benzophenones, 2-hydroxyphenyl benzotriazoles, hindered amines and organic nickel compounds. In addition, salicylates, cinnamate derivatives, resorcinol monobenzoates, oxanilides, and p-hydroxy benzoates are used as well.

The compositions may also contain dyes. The dyes present in the photopolymer composition must not interfere with the imagewise exposure and should not absorb actinic radiation too strongly in the region of the spectrum that the initiator, present in the composition is activatable.

The improved photosensitive resin compositions of the instant invention can be imaged using mercury and xenon lamps and their doped variants, plasma lamps, and laser sources. Suitable laser sources include argon ion lasers, solid-state lasers, and diode-type lasers, although other laser sources would also be known to one skilled in the art.

Depending on the chemistry of the resin system, conventional plate processing steps can be used, including solvent washing, water washing, high-pressure water spray, and thermal blotting.

In accordance with another aspect of the invention, there are provided printing plates comprising a suitable substrate and a layer of photosensitive resin composition deposited thereupon. The improved photosensitive resin compositions of the instant invention can be used to formulate either the base photopolymerizable layer or for formulating an intermediate capping layer in the flexographic plate.

The photosensitive resin composition may be deposited onto the substrate in a variety of ways, e.g., by extrusion, roll coating, heat processing, solvent casting, and the like. These techniques can be readily carried out by those skilled in the art. Preferably, the photosensitive resin composition is laminated onto a suitable solid substrate. The thickness of the photopolymerizable layer can range from about 0.5 mil to 250 mil or more.

A variety of substrates may be used with the photosensitive compositions. The term “substrate” means any solid layer giving support and stability to the photosensitive resin plus an optional adhesion layer. Presently preferred substrates contemplated for use in the practice of the present invention include natural or synthetic materials that can be made into a rigid or flexible sheet form. These materials include steel, copper, or aluminum sheets, plates, or foils, paper, or films or sheets made from synthetic polymeric materials such as polyesters, polystyrene, polyolefins, polyamides, and the like.

Selected portions of the resin compositions are exposed to actinic radiation, crosslinking said portions. The unexposed portions of the resin composition are washed away in a suitable solvent or dispersant, preferably an aqueous solution, leaving behind the desired image on the printing plate.

The desired image is produced on the printing plate by exposing selected portions of the resin to actinic radiation. Selective exposure of the photosensitive resin can be achieved for example, by the use of an image-bearing transparency such as a negative film held in close proximity to the surface of the photosensitive layer, through the front side of the photosensitive resin. Areas of the transparency opaque to actinic radiation prevent the initiation of polymerization within the photosensitive layer directly beneath the transparency. Transparent areas of the image-bearing element will allow the penetration of actinic radiation into the photosensitive layer, initiating polymerization, rendering those areas insoluble or non-dispersible in the processing solvent. Alternatively, exposure of selected portions of the photosensitive layer to laser radiation may also initiate polymerization, rendering those areas insoluble in the processing solvent dispersant. The unexposed portions of the resin are selectively removed by thermal blotting or washing in a suitable solvent. Washing may be accomplished by a variety of processes, including brushing, spraying, or immersion.

The invention will now be described in detail by reference to the following non-limiting examples:

### COMPARATIVE EXAMPLE 1

A water-developable photosensitive resin composition was formulated as follows:

Part A: 280.50 parts of a polyoxyalkylene mono-phenyl ether manufactured by Dai-Ichi Kogyo Seiyaku Co. Ltd.; 148.50 parts of a C₁₂₋₁₄-t-alkyl ethoxylated amine manufactured by Union Carbide (RW-100, trade name of this company); 165.00 parts of polybutadiene dimethacrylate manufactured by Sartomer Comp. (CN303, a trade name of the company); 172.00 parts of a polyethylene glycol diacrylate manufactured by Sartomer Co. (SR344, a trade name of this company); 148.50 parts of a propoxylated trimethylolpropane triacrylate manufactured by Sartomer Co. (CD501, a trade name of this company); 132.00 parts of lauryl acrylate manufactured by Sartomer Co. (SR335, a trade name of this company); 49.50 parts of a 1,6-hexanediol dimethacrylate manufactured by Sartomer Co. (SR239, a trade name of this company); 132.00 parts of a dimethyl aminopropyl methacrylamide manufactured by Rohm America Inc. (BM-611, a trade name of this company); were mixed at room temperature, followed by dissolving 3.30 parts of butylated hydroxy toluene manufactured by Sherex Chemical Co. Inc. (Cresol, a trade name of this company); 42.90 parts of 1-hydroxycyclohexyl phenyl ketone manufactured by Ciba Additives (Irgacure-184, a trade name of this company); and 13.20 parts of diphenyl (2,4,6-trimethylbenzyl)phosphine oxide manufactured by BASF Corp. (Lucerin TPO, a trade name of this company).

Resin mixing: 1590.00 parts of a particulate copolymer manufactured by JSR Corp., which is an emulsion copolymer of butadiene/methacrylic acid/divinylbenzene/methyl methacrylate=80/6.5/1.0/12.5 (weight %) (see EP 0 607 962 A1, U.S. Pat. No. 6,140,017); 240.00 parts of a styrene-isoprene-styrene block copolymer manufactured by Kraton Co. (Kraton DI 107, a trade name of this company); and 1170.12 parts of Part A were mixed in a Monlyama mixer at 80° C. Part A was introduced to the mixer in seven separate aliquots.

Physical property evaluation: Two samples of 3.00 mm thick photosensitive resin produced as described above were heat-pressed (Heat Press, Lake Erie Engineering Corp.) in a 8 cm×8 cm mold at 70° C. The samples were completely exposed under NAPP Exposure Unit-IT on each side for 5 minutes. The exposed samples were tested for hardness (Shore Durometer, Type A-2, the Shore Instrument & MFG. Co.) and resilience (Resilimeter model SR-1, the Shore Instrument & MFG. Co.). A sample of the photosensitive resin with 0.6 mm thickness was heat-pressed at 70° C. The sample was divided into twenty 5 cm×1 cm pieces for tensile testing (Instron-5543, Instron Corp.). The results obtained are shown in Table 1.

### EXAMPLE 2

A water-developable photosensitive resin composition was formulated as follows:

Part A: 269.94 parts of a polyoxyalkylene mono-phenyl ether manufactured by Dai-Ichi Kogyo Seiyaku Co. Ltd.; 142.90 parts of a C₁₂₋₁₄-t-alkyl ethoxylated amine manufactured by Union Carbide (RW-100, trade name of this company); 158.80 parts of polybutadiene dimethacrylate manufactured by Sartomer Co. (CN303, a trade name of this company); 158.78 parts of a polyethylene glycol diacrylate manufactured by Sartomer Co. (SR344, a trade name of this company); 142.90 parts of a propoxylated trimethylolpropane triacrylate manufactured by Sartomer Co. (CD501, a trade name of this company); 127.00 parts of lauryl acrylate manufactured by Sartomer Co. (SR335, a trade name of this company); 50.82 parts of a 1,6-hexanediol dimethacrylate manufactured by Sartomer Co. (SR239, a trade name of this company); 127.00 parts of a dimethyl aminopropyl methacrylamide manufactured by Rohm America Inc. (BM-611, a trade name of this company); were mixed at room temperature, followed by dissolving 3.16 parts of butylated hydroxy toluene manufactured by Sherex Chemical Co. Inc. (Cresol, a trade name of this company); 44.44 parts of 1-hydroxycyclohexyl phenyl ketone manufactured by Ciba Additives (Irgacure-184, a trade name of this company); and 13.02 parts of diphenyl (2,4,6-trimethylbenzyl)phosphine oxide manufactured by BASF Corp. (Lucerin TPO, a trade name of this company), finally, 165.10 parts of a montmorillonite clay supplied by Nanocor (Nanomer 1.34 TCN, trade name of the company) was suspended into the liquid solution with mechanical stirring.

Resin mixing: 1500.00 parts of a particulate copolymer, as in Example 1, 226.42 parts of the Kraton D1107; and 1276.18 parts of Part A were mixed in a Moriyama mixer at 80° C. Part A was introduced to the mixer as seven separate aliquots.

Physical property evaluation: The methods set forth in Example 1 were used to evaluate the physical properties of the formulation prepared according to Example 2. The results obtained are shown in Table 1.

TABLE 1
Physical Properties of Prepared Formulations of Examples 1-2

| | Tensile | Elongation | | Impact | |
|---|---|---|---|---|---|
| | Strength | At Break | Toughness | Resilience | Hardness |
| Example | (gf/mm²) | (%) | g/mm² | (%) | (Shore A) |
| 1 (Compa- | 377 | 89 | 100 | 27 | 73 |
| rative) | | | | | |
| 2 (Invention) | 608 | 89 | 173 | 27 | 75 |

### COMPARATIVE EXAMPLE 3

A mixture of 5.6 parts of 1,6-hexanediol diacrylate manufactured by Sartomer Co. (SR-238, a trade name of this company), 5.6 parts of trimethylolpropane trimethacrylate manufactured by Sartomer Co. (SR-350, a trade name of this company), 2.8 parts of benzil dimethyl ketal manufactured by Ciba Specialty Chemicals (Irgacure 651, a trade name of this company), 1.2 parts of 2,6-di-tert-butyl-p-cresol manufactured by Sherex Chemical Company (Cresol, a trade name of this company), 0.17 part of calcium stearate manufactured by Spectrum Chemical Corporation, 0.04 part of an antioxidant manufactured by Ciba Specialty Chemicals (Irganox 1010, a trade name of this company) and 0.006 parts of a dye manufactured by Clariant Corp. (Sandoplast Red Violet R, a trade name of this company) was stirred until all the solid components were dissolved.

79.8 parts styrene-isoprene-styrene block copolymers manufactured by Kraton Polymers (Kraton D-1107, a trade name of this company) were mixed with 4.8 parts of plasticizer manufactured by Astro Chemicals (Shellflex 371, a trade name of this company) in a HAAKE® mixer at 105° C. until well blended. Incremental amounts of the above solution were added to the polymer. The resin was mixed until homogenous.

The resulting resin was used to mold a layer about 0.067 inch-thick on a base consisting of a polyester substrate coated with an adhesive layer. A release layer and a cover sheet were applied on the imaging side.

The material prepared was processed to a relief printing plate in a conventional manner by pre-exposing the material to actinic light from its back. Then, the cover sheet was removed and the recording layer was exposed imagewise, through an image-bearing transparency, to actinic light having a strong emission at 360 nm. The unexposed areas of the layer were removed by washing out with suitable solvent or thermal blotting. The resulting solvent processed printing plate was then dried and post-exposed with actinic lights. Image quality of the processed plate was evaluated. The printing plate obtained possessed excellent image quality.

Samples of the material were also prepared for Instron® 5543 physical property evaluation. The material was molded to 0.8 mm thick and each side was exposed to actinic light for 5 minutes. Instron® 5543 DIN 53504-S3 die cutter was used to cut 16 samples from the exposed material. The results obtained are shown in Table 2.

Shore A hardness of an exposed material was measured by following the ASTM method D 2240-86 while resilience was measured by following ASTM method D-2632-88. The results obtained are shown in Table 2.

### EXAMPLE 4

The procedure described in Comparative Example 4 was followed, except that an additional 5.0 parts of a montmorillonite clay manufactured by Nanocor (Nanomer I.34 TCN, a tradename of this company), was added to the resin while mixing in the HAAKE® mixer. The resin was mixed until well blended.

The methods set forth in Comparative Example 3 were used to evaluate the physical property of formulation prepared according to Example 4.

TABLE 2
Physical Properties of Prepared Formulations of Examples 3-4

| | Tensile | | | | Impact |
|---|---|---|---|---|---|
| | Strength | Elongation | Toughness | Hardness | Resilience |
| Example | (gf/mm²) | (%) | (kgf/mm²) | (Shore A) | (%) |
| 3 (Compa- | 870 | 631 | 3.17 | 59 | 56 |
| rative) | | | | | |
| 4 (Invention) | 1040 | 756 | 4.64 | 65 | 56 |

The material obtained from Example 4 gave significantly higher tensile strength, elongation, and toughness values. The hardness increased six points while the resilience remained the same.

### COMPARATIVE EXAMPLE 5

A mixture of 6.00 parts 1,6-hexanediol diacrylate manufactured by Sartomer Co. (SR-238, a trade name of this company), 1.50 parts of benzil dimethyl ketal manufactured by Ciba Specialty Chemicals (Irgacure 651, a trade name of this company), 1.50 parts of 2,6-di-tert-butyl-p-cresol manufactured by Sherex Chemical Company (Cresol, a trade name of this company), and 0.008 parts a dye manufactured by Rite Industries, Inc. (Ricosolve Red 3GL, a trade name of this company) was stirred until homogeneous.

A solution of 26.44 parts of a plasticizer manufactured by Astro Chemicals (Shellflex 371, a trade name of this company) was added slowly and incrementally to 64.55 parts styrene-butadiene-styrene block copolymers manufactured by Kraton Polymers (Kraton D-1102, a trade name of this company) while mixing in the HAAKE® mixer at 105° C. After complete addition, the resin was mixed until homogeneous.

The resulting material was used to mold a 2-inch×2-inch×0.11-inch resin sample. Three samples were prepared for the following evaluation:

A digital micrometer with ⅜″ foot and equipped with removable 1100 gram weight was used to measure compression resistance of the material. At room temperature, the initial thickness of the material was measured with the micrometer without the 1100 gram weight. The foot of the micrometer was lifted to prevent further impression and the 1100-gram weight was applied to the micrometer shaft. The foot was gently lowered to the plate surface then released. After 30 seconds, a thickness reading was immediately taken and the weight quickly removed. After an additional 120 seconds, another thickness measurement was taken. Triplicate analysis produced the average thickness changes and percentage changes shown in Table 3. These results represent the tendency of the resin to undergo flow at room temperature.

### EXAMPLE 6

The procedure described in Comparative Example 5 was followed except that 5.00 parts of a montmorillonite clay manufactured by Nanocor (Nanomer I.34 TCN, a trade name of this company) was added to the resin while mixing in the HAAKE® mixer. The resin was mixed until well blended.

The method set forth in Comparative Example 5 was used to evaluate the cold flow of the material prepared according to Example 6. The results obtained were compared to that obtained with the material described in Comparative Example 5. The results are demonstrated in Table 3.

TABLE 3
Tendency of Resin to Undergo Flow at Room Temperature

| | | | After | |
|---|---|---|---|---|
| | After 30 Seconds with | | Additional 120 Seconds | |
| | 1100 gram Weight | | without Weight | |
| | Thickness | % Thickness | Thickness | % Thickness |
| Example | Change | Change | Change | Change |
| 5 (Comparative) | 40.5 mils | 35.4% | 14.6 mils | 12.8% |
| 6 (Invention) | 28.2 mils | 24.4% | 8.1 mils | 7.0% |

As is readily seen in Table 3, addition of nano-sized montmorillonite clay in the photopolymer resin reduces the tendency of the uncured resin to flow.

What is claimed is:

1. An improved photosensitive resin composition for use in making a flexographic printing plate, said resin composition comprising:
a) a base polymer;
b) a reactive crosslinking agent;
c) a photoinitiator; and
d) a filler, wherein said filler comprises nanoparticles.

2. A resin composition according to claim 1, wherein said base polymer is selected from the group consisting of styrene-isoprene and styrene-isoprene-styrene block copolymers, styrene-butadiene and styrene-butadiene-styrene block copolymers, urethane-based systems, polyvinyl alcohol-based systems, cross-linked latex particle-based systems, and mixtures of the foregoing.

3. A resin composition according to claim 1, wherein said nanoparticles comprise modified nanoclay particles.

4. A resin composition according to claim 1, wherein said nanoparticles are present in said resin composition at a concentration of less than 25% by weight.

5. A resin composition according to claim 4, wherein said nanoparticles are present in said resin composition at a concentration of less than 15% by weight.

6. A resin composition according to claim 5, wherein said nanoparticles are present in said resin composition at a concentration of less than 10% by weight.

7. A resin composition according to claim 1, wherein said nanoparticles have a maximum diameter of less than 1,000 nm.

8. A resin composition according to claim 7, wherein said nanoparticles have a maximum diameter of less than 100 nm.

9. A resin composition according to claim 8, wherein said nanoparticles have a maximum diameter of less than 10 nm.

10. A resin composition according to claim 1, wherein said nanoparticles have a mean dry particle size of 2 to 22 microns.

11. A resin composition according to claim 1, further comprising at least one additional component selected from the group consisting of inhibitors, dyes, plasticizers, antiozonants, additives, and combinations of the foregoing.

12. A method of making a flexographic printing plate, comprising the steps of:
a) providing a photosensitive resin composition comprising:
i) a base polymer;
ii) a reactive crosslinking agent;
iii) a photoinitiator; and
iv) a filler, wherein said filler comprises nanoparticles; wherein said photosensitive resin composition is on a substrate; and
b) selectively imaging said photosensitive resin composition to cross-link selective portions and provide a desired image on a surface of the photosensitive resin composition.

13. A method according to claim 12, wherein said base polymer is selected from the group consisting of styrene-isoprene and styrene-isoprene-styrene block copolymers, styrene-butadiene and styrene-butadiene-styrene block copolymers, urethane-based systems, polyvinyl alcohol-based systems, cross-linked latex particle-based systems, and mixtures of the foregoing.

14. A method according to claim 12, wherein said nanoparticles comprise modified nanoclay particles.

15. A method according to claim 12, wherein said nanoparticles are present in said resin composition at a concentration of less than 25% by weight.

16. A method according to claim 15, wherein said nanoparticles are present in said resin composition at a concentration of less than 15% by weight.

17. A method according to claim 16, wherein said nanoparticles are present in said resin composition at a concentration of less than 10% by weight.

18. A method according to claim 12, wherein said nanoparticles have a maximum diameter of less than 1,000 nm.

19. A method according to claim 18, wherein said nanoparticles have a maximum diameter of less than 100 nm.

20. A method according to claim 19, wherein said nanoparticles have a maximum diameter of less than 10 nm.

21. A method according to claim 12, wherein said nanoparticles have a mean dry particle size of 2 to 22 microns.

22. A method according to claim 12, further comprising at least one additional component selected from the group consisting of inhibitors, dyes, plasticizers, antiozonants, additives, and combinations of the foregoing.
